(19) United States
(12) Patent Application Publication
(10) Pub. No.: US 2011/0007577 A1
(43) Pub. Date: Jan. 13, 2011

(54) ACCESSING METHOD AND A MEMORY USING THEREOF

(75) Inventors: Tsung-Yi Chou, Hsinchu County (TW); Ming-Feng Zhou, Taipei County (TW); Chung-Yi Li, Pingtung County (TW); Zong-Qi Zhou, Taoyuan County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MACRONIX INTERNATIONAL CO., LTD., Hsinchu (TW)

(21) Appl. No.: 12/500,826

(22) Filed: Jul. 10, 2009

(51) Int. Cl. G11C 7/06; G11C 7/02

(52) U.S. Cl. 365/189.07; 365/207

(57) ABSTRACT

A memory comprises a memory cell, a sense amplifier, and a control unit. The memory cell stores a first bit and a second bit. The sense amplifier senses a first cell current and a second cell current corresponding to the first and the second bits respectively with a voltage applying on the memory cell. The control unit determines a digital state of the first bit by comparing a first reference current with the first cell current or by comparing a reference data with a first delta current between the first cell current and the second cell current.

### BACKGROUND OF THE INVENTION

1. Field of the Invention

The invention relates in general to an accessing method for a memory, and more particularly to an accessing method for a memory with multi-bit cells.

2. Description of the Related Art

Along with increasing development of technology, non-volatile memory, such as flash memory, has been wildly used in electronic product. For example, a flash memory includes a number of memory cells, each of which stores a bit of data. Each of the memory cells corresponds with a programmable threshold voltage indicating a logic value of the bit of data.

Referring to FIG. 1, an illustration for threshold voltages distribution of a conventionally flash memory is shown. For example, a reference voltage PV is applied as a judging criterion. Bits of data corresponding to threshold voltages smaller than the reference voltage PV, as shown as a group of bits of data A, are programmed with a low-threshold-voltage state. It is determined that the bits of data in group A indicate logic value “1”. Bits of data corresponding to threshold voltages larger than the reference voltage PV, as shown as a group of bits of data B, are programmed with a high-threshold-voltage state. It is determined that the bits of data in group B indicate logic value “0”.

In the conventionally flash memory, the bits of data in the group B must be programmed with threshold voltages higher than the reference voltage PV and the reference voltage PV must be higher than a highest threshold voltage Vthl_h, which indicates the highest threshold voltage corresponded by the bits of data in the group A, by a margin, otherwise the conventionally flash memory cannot be properly read. Therefore, a reference voltage with high voltage level, a great number of program shots, and a great period of program time are disadvantageously needed for the conventionally flash memory.

### SUMMARY OF THE INVENTION

The invention is directed to an accessing method for a memory with a number of memory cells, each of which is capable of storing two bits of data. The accessing method according to the invention applies lower reference voltage PV in program operation. Besides, the accessing method according to the invention can effectively read the data stored in the memory even the distribution of memory cells with high-threshold-voltage state and that of the memory cells with low-threshold-voltage state are substantially overlapped with each other. Thus, in comparison with the conventional accessing method, the accessing method according to the invention can effectively reduce the program shots and shorten the corresponding program time.

According to a first aspect of the present invention, a memory, which comprises a memory array, a first operation circuit, and a second operation circuit, is provided. The memory array includes a memory cell for storing a first bit and a second bit. The first operation circuit operates the first and the second bits with substantially the same initial threshold voltage state to a final threshold voltage stat by applying a same number of operating shots. The second operation circuit includes a sense amplifier and a control unit. The sense amplifier senses a first cell current and a second cell current corresponding to the first and the second bits respectively. The control unit determines a digital state of the first bit by comparing a reference data with a first delta current between the first cell current and the second cell current.

According to a second aspect of the present invention, a memory, which includes a memory cell, a sense amplifier and a control unit, is provided. The memory cell stores a first bit and a second bit. The sense amplifier senses a first cell current and a second cell current corresponding to the first and the second bits respectively with a voltage applying on the memory cell. The control unit determines a digital state of the first bit by comparing a first reference current with the first cell current or by comparing a reference data with a first delta current between the first cell current and the second cell current.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is an illustration for threshold voltages distribution of a conventionally flash memory.

FIG. 2 is a block diagram of a memory according to the present embodiment of the invention.

FIG. 3A is an illustration of an initial threshold voltages distribution of the memory array 12.

FIG. 3B is an illustration of a programmed threshold voltages distribution of the memory array 12.

FIG. 4 is a detail block diagram of the read circuit according to the present embodiment of the invention.

FIG. 5 is a flow chart of the accessing method according to the present embodiment of the invention.

FIG. 6 is a flow chart of the accessing method according to the present embodiment of the invention.

FIG. 7 is a program method according to the present embodiment of the invention.

FIG. 8 is a detailed block diagram of the control circuit 1 6b of FIG. 4.

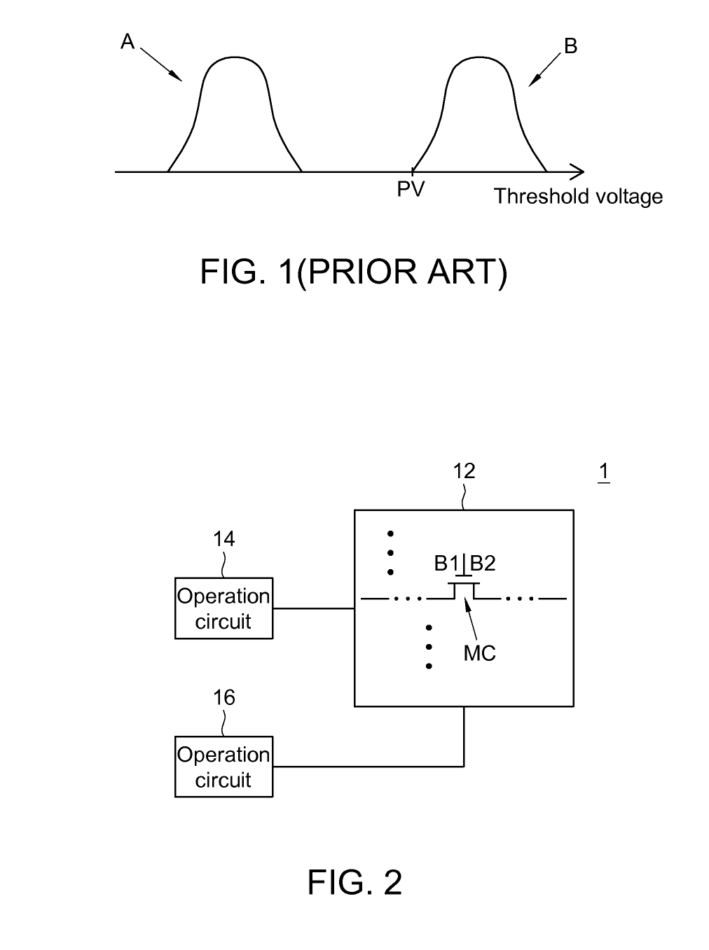

### DETAILED DESCRIPTION OF THE INVENTION

The accessing method according to the present embodiment of the invention applies the information of whether a first cell current and a second cell current, which correspond with a first bit of data and a second bit of data respectively stored in a memory cell of a memory, are substantially close to each other to determine the programmed state of the first and the second bits of data.

Referring to FIG. 2, a block diagram of a memory according to the present embodiment of the invention is shown. The memory 1, a flash memory for example, includes a memory array 12, operation circuits 14 and 16. The memory array 12 includes numerous memory cells, each of which stores two bits of data. The operation circuit 16 is, for example, a read circuit for reading data stored in the memory array 12. The operation circuit 14, which is a program circuit, for example, programs the memory cells for storing those bits of data. For example, the bits of data stored in each of the memory cells can be programmed to have a high-threshold-voltage state indicating a logic value 0 or can be programmed to have a low-threshold-voltage state indicating a logic value 1.

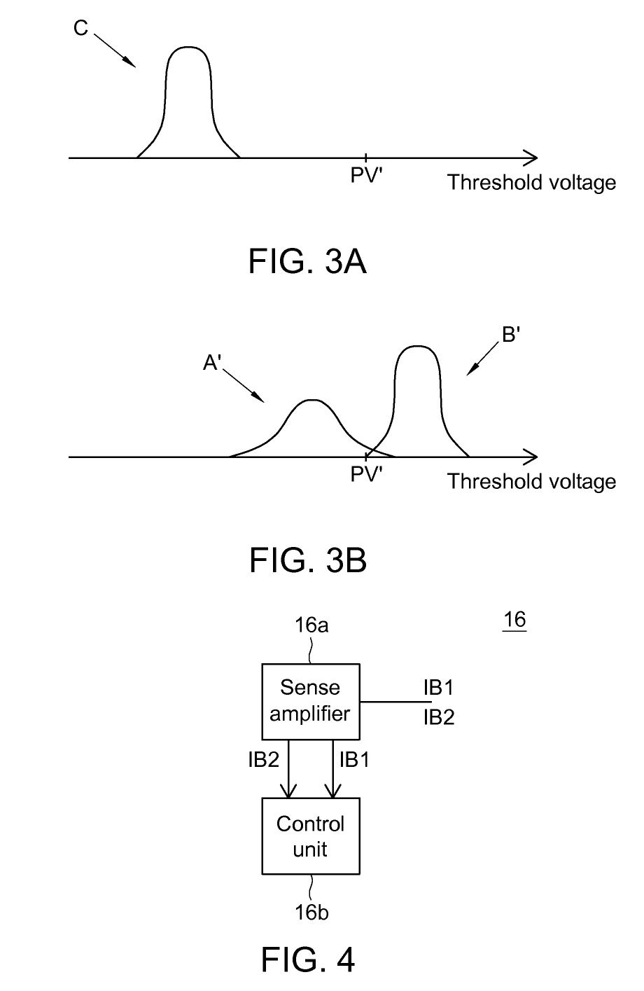

Referring to FIG. 3A, an illustration of an initial threshold voltages distribution of the memory array 12 is shown. For example, all of the bits of data are initiated to have an initial state C, in which the threshold voltages corresponding to the bits of data are all smaller than a reference voltage PV′. For each of the memory cells, the initial threshold voltages corresponding to the two bits of data stored in each of the memory cells are close to each other. In an example, for each of the memory cells, the two bits of data stored therein correspond to a same initial threshold voltage. Besides, for each of the memory cells, the two bits of data are included in a same program block. In other words, a same number of program shots are applied by the operation circuit 14 to the two bits of data stored in each of the memory cells when the two bits of data are about to be programmed to have the high-threshold-voltage state. Thus, when the two bits of data stored in each of the memory cells are programmed to be the same state (either the low-threshold-voltage state or the high-threshold-voltage state), the two bits of data correspond to substantially the same threshold voltages.

Referring to FIG. 3B, an illustration for a programmed threshold voltages distribution of the memory array 12 is shown. The threshold voltages corresponding to the bits of data having the high-threshold-voltage state are programmed to be lager than a reference voltage PV′. For example, after the program operation performed by the operation circuit 14, a group of bits of data B′ corresponding to the high-threshold-voltage state are formed. The threshold voltages corresponding to the group of bits of data B′ are lager than the reference voltage PV′.

Other than the group B′, the rest of the bits of data are not programmed so as to form a group of bits of data A′ corresponding to the low-threshold-voltage state. Most of those bits of data in group A′ correspond to threshold voltages smaller than the reference voltage PV′. Some bits of data in group A′ correspond to threshold voltages, which are raised to be larger than the reference voltage PV′ due to the second-bit effect. In other words, a bit of data having the high-threshold-voltage state is stored in memory cells storing the respective bits of data in group A′ corresponding to threshold voltages larger than the reference voltage PV′. That is to say those bits of data in group A′ corresponding to threshold voltages larger than the reference voltage PV′ are stored in memory cells with data indicating the two logic values 1 and 0.

Thus, judging criteria must be applied by the operation circuit 16 to effectively read those bits of data, which have the low-threshold-voltage state but correspond to threshold voltages larger than the reference voltage PV′. In an example, the cell currents corresponding to the two bits of data stored in a memory cell are applied by the operation circuit 16 to spot those bits of data having the low-threshold-voltage state but correspond to threshold voltages larger than the reference voltage PV′. Since the read operation performed on those memory cells are substantially the same, only the read operation performed on a memory cell MC is cited as an example in the following paragraphs. For example, the memory cell MC storing a first bit of data B1 and a second bit of data B2.

Referring to FIG. 4, a detail block diagram of the operation circuit 16 according to the present embodiment of the invention is shown. The operation circuit 16 includes a sense amplifier 16a and a control unit 16b. The sense amplifier 16a senses first cell current IB1 and second cell current IB2 corresponding to the first and the second bits of data B1 and B2 respectively.

In the operation for reading the first bit of data B1, the control unit 16b determines whether the first cell current IB1 is larger than a reference current to determine whether the threshold voltage corresponding to the first bit of data B1 is larger than the reference voltage PV′. If the first cell current IB1 is larger than the reference current (indicating the threshold voltage corresponding to the first bit of data B1 is not larger than the reference voltage PV′), the first bit of data B1 must be programmed to have the low-threshold-voltage state. Thus, the control unit 16b determines that the first bit of data B1 indicates the logic value 1 if the first cell current IB1 is larger than the reference current (that is the threshold voltage corresponding to the first bit of data B1 is not larger than the reference voltage PV′).

If the first cell current IB1 is not larger than the reference current (indicating the threshold voltage corresponding to the first bit of data B1 is larger than the reference voltage PV′), the first bit of data B1 may be programmed to have the low-threshold-voltage state or the high-threshold-voltage. The control unit 16b further determines whether a first delta current between the first cell current IB1 and the second cell current IB2 is larger than reference data to determine whether the first and the second bits of data B1 and B2 respectively indicating the logic values 1 and 0. For example, the first delta current is obtained by subtracting the second cell current IB2 from the first cell current IB1. Thus, whether the first bit of data B1 is one of those bits of data having the low-threshold-voltage state but correspond to threshold voltages larger than the reference voltage PV′ can be determined.

For example, the reference data is chosen based on an average difference between the two cell currents corresponding to the two bits of data with logic values 0 and 0 stored in each memory cells of the memory array 12 and that with logic values 0 and 1 measured in an experiment. In an example, the average difference corresponding to the two bits of data with logic values 0 and 0 has the value of 0.875 micro-ampere (μA) and the average difference corresponding to the two bits of data with logic values 0 and 1 has the value of 15.063 μA. The reference data are set based on the average value of the two average differences (0.875 and 15.063 μA). In other words, the reference data has the value of 7.968 μA.

If the first delta current is larger than the reference data, it is suggested that the first and the second bits of data B1 and B2 respectively indicate the logic values 1 and 0 and the first bit of data B1 is one of those bits of data in group A′ but corresponding to a threshold voltage larger than the reference voltage PV′. Thus, the control unit 16b accordingly determines that the first bit of data B1 indicates the logic value 1 if the first delta current is larger that the reference data.

If the first delta current is not larger than the reference data, it is suggested that the first and the second bits of data B1 and B2 are not respectively indicate the logic values 1 and 0 and the first bit of data B1 is not one of those bits of data in group A′ but corresponding to a threshold voltage larger than the reference voltage PV′. It is suggested that the first bit of data B1 is one of those bits of data in group B′. Thus, the control unit 16b accordingly determines that the first bit of data B1 indicates the logic value 0 if the first delta current is not larger that the reference data. Therefore, the first bit of data B1 stored in the memory cell MC can be effectively read.

In the operation for reading the second bit of data B2, the operation circuit 16 performs similar operation as that shown above to determine whether the second cell current IB2 is larger than the reference current (to accordingly determine whether the threshold voltage corresponding to the second bit of data B2 is not larger than the reference voltage PV′) and whether a second delta current, which is obtained by subtracting the first cell current IB1 from the second cell current IB2, is larger than the reference data. Therefore, the second bit of data B2 stored in the memory cell MC can be effectively read.

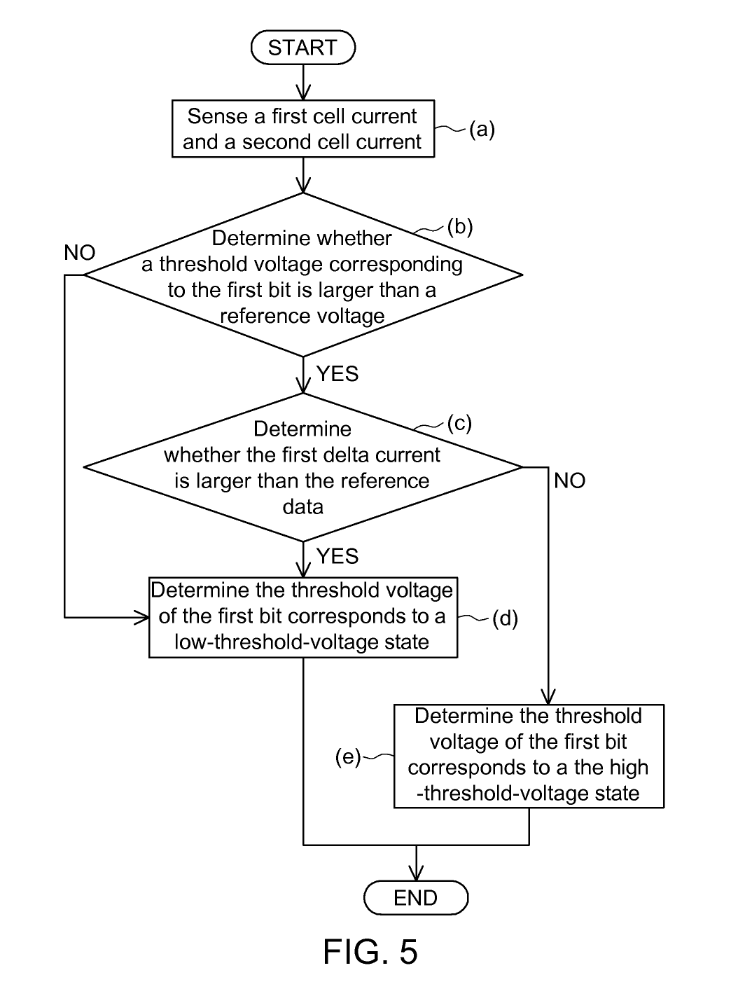

Referring to FIG. 5, a flow chart of the accessing method according to the present embodiment of the invention is shown. The accessing method includes the following steps. First, as shown in step (a), the sense amplifier 16a senses the first cell current IB1 and the second cell current IB2 corresponding to the first and the second bits of data B1 and B2 respectively. Next performing step (b), the control unit 16b determines whether the first cell current IB1 is larger than the reference current to determine whether the threshold voltage corresponding to the first bit of data B1 is larger than the reference voltage PV′. Next performing step (c), the control unit 16b further determines whether the first delta current, which is obtained by subtracting the second cell current IB2 from the first cell current IB1, is larger than the reference data.

If the first delta current is larger than the reference data and the threshold voltage corresponding to the first bit of data B1 is larger than the reference voltage PV′, step (d) is performed such that the operation circuit 16 determines the first bit of data B1 corresponds to the low-threshold-voltage state. If the first delta current is not larger than the reference data, step (e) is performed such that the operation circuit 16 determines the first bit of data B1 corresponds to the high-threshold-voltage state.

If the first cell current IB1 is larger than the reference current (indicating the threshold voltage corresponding to the first bit of data B1 is not larger than the reference voltage), step (d) is also performed such that the operation circuit 16 determines the first bit of data B1 corresponds to the low-threshold-voltage state.

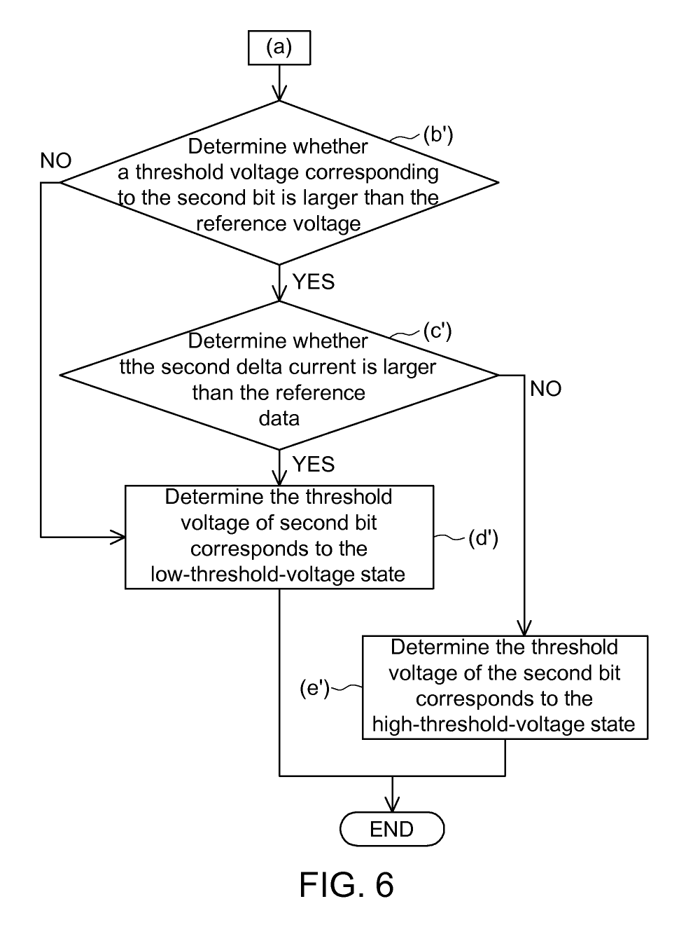

The steps shown in FIG. 5 is for accessing the first bit of data B1 and the steps, and the steps for accessing the second bit of data B2 is shown in FIG. 6. After step (a), step (b′) is performed such that the control unit 16b determines whether the second cell current IB2 is larger than the reference current to determine whether the threshold voltage corresponding to the second bit of data B2 is larger than the reference voltage PV′. Next, step (c′) is performed such that the control unit 16b determines whether the second delta current, which is obtained by subtracting the first cell current IB1 from the second cell current IB2, is larger than the reference data.

If the second delta current is larger than the reference data and the threshold voltage corresponding to the second bit of data B2 is larger than the reference voltage PV′, step (d′) is performed such that the operation circuit 16 determines the second bit of data B2 corresponds to the low-threshold-voltage state. If the second delta current is not larger than the reference data, step (e′) is performed such that the operation circuit 16 determines the second bit of data B2 corresponds to the high-threshold-voltage state.

If the second cell current IB2 is larger than the reference current (indicating the threshold voltage corresponding to the first bit of data B1 is not larger than the reference voltage), step (d) is also performed such that the operation circuit 16 determines the first bit of data B1 corresponds to the low-threshold-voltage state.

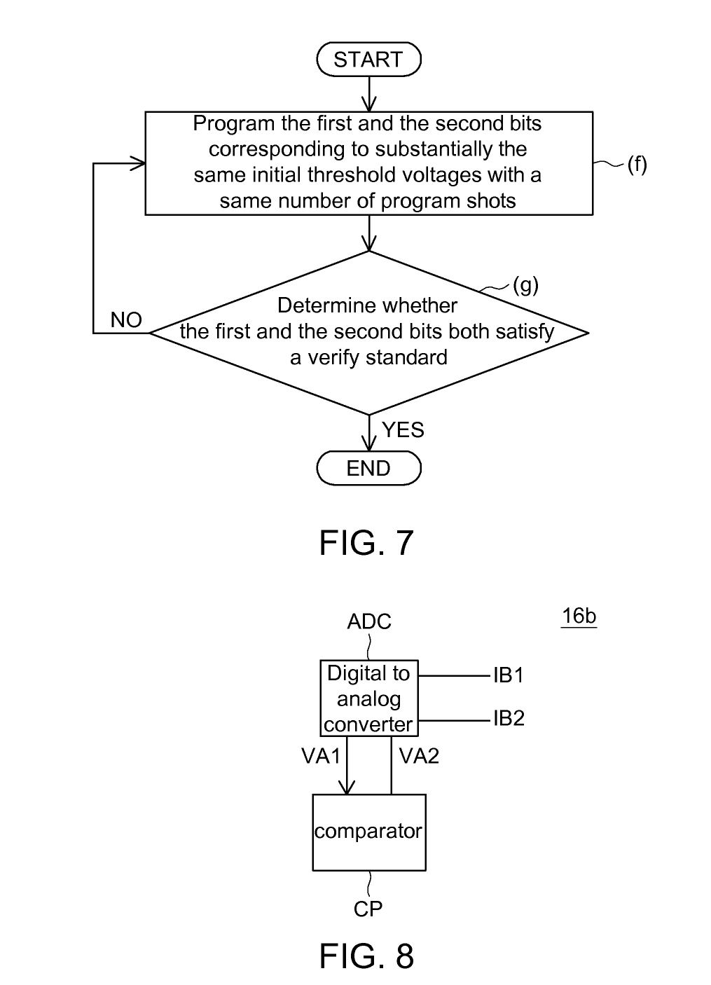

Referring to FIG. 7, a program method according to the present embodiment of the invention is shown. The program method includes the following steps. First, as shown in step (f), the operation circuit 14 programs the first and the second bits of data B1 and B2, which correspond to close initial threshold voltages, with a same number of program shots when the first and the second bits of data B1 and B2 are both about to be programmed with a high-threshold-voltage state. Then performing step (g), the operation circuit 14 further determines whether the first and the second bits of data b1 and b2 both satisfy a verify standard, if not, repeat step (f) to re-program the first and the second bits of data B1 and B2.

Referring to FIG. 8, a detailed block diagram of the control unit 16b of FIG. 4 is shown. For example, the control unit 16 comprises a digital to analog converter ADC and a comparator CP. The digital to analog converter ADC converts the first and the second cell currents IB1 and IB2 to a first digital value VA1 and a second digital value VA2 respectively. The comparator CP determines the first delta current by comparing the first and the second digital values VA1 and VA2. The comparator CP further determines the second delta current by comparing the first and the second digital values VA1 and VA2.

The accessing method according to the present embodiment is for a memory with a number of memory cells, each of which is capable of storing two bits of data. The accessing method according to the present embodiment of the invention can effectively read the data stored in the memory even the distribution of memory cells with high-threshold-voltage state and that of the memory cells with low-threshold-voltage state are substantially overlapped with each other based on the information of whether a first cell current and a second cell current, which correspond with a first bit of data and a second bit of data respectively stored in a memory cell of the memory are substantially close to each other. Thus, in comparison with the conventional accessing method, the accessing method according to the present embodiment of the invention can effectively reduce the program shots and shorten the corresponding program time and reduce the voltage level of the reference voltage applied as the as a judging criterion of program states.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A memory, comprising:
a memory array, comprising a memory cell for storing a first bit and a second bit;
a first operation circuit for operating the first and the second bits with substantially the same initial threshold voltage state to a final threshold voltage stat by applying a same number of operating shot; and
a second operation circuit, comprising:
a sense amplifier for sensing a first cell current and a second cell current corresponding to the first and the second bits respectively; and
a control unit for determining a digital state of the first bit by comparing a reference data with a first delta current between the first cell current and the second cell current.

2. The memory according to claim 1, wherein:
the first delta current is obtained by subtracting the second cell current from the first cell current; and
the control unit further compares the first cell current and a reference current.

3. The memory according to claim 2, wherein the control unit determines the first bit corresponds to a low-threshold-voltage state if the first delta current is larger than the reference data and the first cell current is not larger than the reference current.

4. The memory according to claim 2, wherein the control unit determines the first bit corresponds to the high-threshold-voltage state if the first delta current is not larger than the reference data and the first cell current is not larger than the reference current.

5. The memory according to claim 2, wherein the control unit determines the first bit corresponds to the low-threshold-voltage state if the first cell current is larger than the reference current.

6. The memory according to claim 1, wherein the control unit further determines a digital state of the second bit by comparing the second cell current and the reference current and by comparing the reference data with a second delta current, which is obtained by subtracting the first cell current from the second cell current, between the first cell current and the second cell current.

7. The memory according to claim 6, wherein the control unit determines the second bit corresponds to a low-threshold-voltage state if the second delta current is larger than the reference data and the second cell current is not larger than the reference current.

8. The memory according to claim 6, wherein the control unit determines the second bit corresponds to the high-threshold-voltage state if the second delta current is not larger than the reference data and the second cell current is not larger than the reference current.

9. The memory according to claim 1, wherein the control unit determines the second bit corresponds to the low-threshold-voltage state if the second cell current is larger than the reference current.

10. The memory according to claim 1, wherein the first operation circuit further determines whether the first and the second bits both satisfy a verify standard, and the first operation circuit reprograms the first and the second bits when the first and the second bits are not both satisfy the verify standard.

11. The memory according to claim 1, wherein the control circuit comprises:
a digital to analog converter, for converting the first cell current to a first digital value and converting the second cell current to a second digital value; and
a comparator, for determining the first delta current by comparing the second digital value and the first digital value.

12. A memory, comprising:
a memory cell for storing a first bit and a second bit;
a sense amplifier for sensing a first cell current and a second cell current corresponding to the first and the second bits respectively with a voltage applying on the memory cell; and
a control unit for determining a digital state of the first bit by comparing a first reference current with the first cell current or by comparing a reference data with a first delta current between the first cell current and the second cell current.

13. The memory according to claim 12, wherein the first delta current is obtained by subtracting the second cell current from the first cell current.

14. The memory according to claim 13, wherein the control unit determines the first bit corresponds to a low-threshold-voltage state if the first delta current is larger than the reference data and the first cell current is not larger than the reference current.

15. The memory according to claim 13, wherein the control unit determines the first bit corresponds to the high-threshold-voltage state if the first delta current is not larger than the reference data and the first cell current is not larger than the reference current.

16. The memory according to claim 12, wherein the control unit determines the first bit corresponds to the low-threshold-voltage state if the first cell current is larger than the reference current.

17. The memory according to claim 12, wherein the control unit further determines a digital state of the second bit by comparing the second cell current and the reference current and comparing the reference data with a second delta current, which is obtained by subtracting the first cell current from the second cell current, between the first cell current and the second cell current.

18. The memory according to claim 17, wherein the control unit determines the second bit corresponds to a low-threshold-voltage state if the second delta current is larger than the reference data and the second cell current is not larger than the reference current.

19. The memory according to claim 17, wherein the control unit determines the second bit corresponds to the high-threshold-voltage state if the second delta current is not larger than the reference data and the second cell current is not larger than the reference current.

20. The memory according to claim 12, wherein the control unit determines the second bit corresponds to the low-threshold-voltage state if the second cell current is larger than the reference current.

21. The memory according to claim 12, further comprising:
an operation circuit, for operating the first and the second bits with substantially the same initial threshold voltage state to a final threshold voltage stat by applying a same number of operating shots, the operation circuit further
determining whether the first and the second bits both satisfy a verify standard, and the first operation circuit reprograms the first and the second bits when the first and the second bits are not both satisfy the verify standard.

22. The memory according to claim 12, further comprising:
a digital to analog converter, for converting the first cell current to a first digital value and converting the second cell current to a second digital value; and
a comparator, for determining the first delta current by comparing the second digital value and the first digital value.
